(19) United States
(12) Patent Application Publication
(10) Pub. No.: US 2023/0224197 A1
(43) Pub. Date: Jul. 13, 2023

(54) CIRCUIT AND METHOD FOR DETERMINING A DITHER AMPLITUDE

(71) Applicant: ZF Friedrichshafen AG, Friedrichshafen (DE)

(72) Inventor: Kristian MÜLLER, Tettnang (DE)

(73) Assignee: ZF Friedrichshafen AG, Friedrichshafen (DE)

(21) Appl. No.: 18/152,531

(22) Filed: Jan. 10, 2023

(30) Foreign Application Priority Data
Jan. 10, 2022 (DE) 10 2022 200 135.4

(51) Int. Cl. H04L 27/08; H04L 27/36; H04L 27/38

(52) U.S. Cl. CPC H04L 27/08; H04L 27/361; H04L 27/3809

(57) ABSTRACT

A dither amplitude circuit has a current circuit for receiving DC voltage signals and generating a direct current on a basis thereof, and generating a dither signal, and a dither current on the basis thereof, applying the dither current to the direct current in order to obtain a drive current, artificially modulating the amplitude of the dither signal or a directly modulated drive current with an amplitude modulation deviation on a periodic basis such that a quantization threshold is reliably exceeded. The dither amplitude circuit also has a return current detection circuit that generates numerous quantized digital values in a time period on a basis of the drive current flowing through a load, such that the dither amplitude can be determined from the numerous digital values.

### CROSS-REFERENCE TO RELATED APPLICATION

This application claims priority to German Application No. DE 10 2022 200 135.4, filed on Jan. 10, 2022, the entirety of which is hereby fully incorporated by reference herein.

### BACKGROUND AND SUMMARY

The present disclosure relates to a circuit for determining a dither amplitude that has an interface for receiving DC voltage signals and generating direct current on the basis of the DC voltage signal and to generate a dither signal and a dither current on the basis thereof, which is applied to the direct current in the form of a dither signal in order to obtain a drive current formed by the direct current combined with the dither current, or to modulate the direct current in the form of a directly modulated drive current until it corresponds to a direct current with the dither current applied thereto, in which the current module contains at least one quantization threshold and an output channel that is coupled to the circuit to control at least one load with the drive current. The present disclosure also relates to a method for determining a dither amplitude.

Switching controllers controlled with PWM (pulse-width modulation) are used for controlling electrohydraulic or electromagnetic actuators, e.g. using a moving (magnetic) anchor in an electric coil. These electric coils move the magnetic anchor and thus the actuator itself.

The position of the anchor acts on the actuator on the basis of the electric current, which can be controlled by the coil.

To minimize stick-slip and hysteresis effects on the actuator, it is useful to superimpose a periodic signal on the current.

For this, the coil can be controlled with a pulse-width modulated (PWM) signal and direct current onto which a dither signal with a low amplitude has been superimposed. These switching controllers are available as integrated circuits (IC).

The source of the modulation or the signal superimposed on the control signal with a vibration of a specific frequency or frequency range is referred to as the dither signal. The dither signal is determined by a frequency, an amplitude, and the shape of the signal. The operating point is the position of the actuator, the volume flow and/or mass flow or pressure, for example.

The dither signal therefore has the function of keeping the actuator's (magnetic) anchor constantly in motion, thus reducing the friction and improving the response behavior of the actuator and the positioning precision or control accuracy that can be obtained.

The dither signal is also referred to as ripple voltage, which lies in a range of ca. 70 to 400 Hz. This causes the magnetic anchor to vibrate slightly, such that it can be controlled better with the direct current.

In the future it will become increasingly more important to monitor the motion of the actuator.

There are two main approaches for this.

First, the movement of the actuator can be detected using a sensor. This approach does not require any fundamental knowledge of the actuator. One disadvantage with using a sensor is the expense involved. Moreover, it is physically difficult to access many actuators, making it extremely difficult or impossible to install sensors for monitoring purposes. Furthermore, sensors often have an effect on the functioning of the actuator.

The movement can also be reconstructed by measuring the electrical parameters, i.e. the drive current. This requires a certain knowledge of the physics of the actuator control, in particular regarding the current flowing through it. This is less expensive and does not require any intervention in the actuator. This approach also has practically no retroactive effects.

There are many methods for determining how much current is flowing through a load, in particular an anchor of this type.

DE 10 2015 222 991 A1 discloses a method and a control device for determining the current flowing through a load in which the current comprises a DC component and a dithering component, and the dithering component is modified at predetermined time intervals, wherein the method comprises steps for detecting a momentary current, determining a dithering parameter, and determining the current on the basis of the momentary current and the dithering parameter.

DE 10 2016 205 312 A1 discloses a method for controlling a current flowing through a load in which the method comprises the following steps, which are carried out on a periodic basis: determining a dither current on the basis of a dither signal and a current time, wherein the dither signal is determined by a frequency, amplitude, and the shape of the signal, controlling a current control valve in order to obtain a value for the combined target current and the determined dither current through the load, comprising the following steps: determining an indicator for the current flowing through the load, compensating for the indicator with the effects of the dither current, and providing the indicator, wherein the determination of the dither current and the determination of the indicator are synchronized to one another in a predetermined manner.

An object of the present disclosure is to create an improved method and an improved circuit for determining the current through the load.

This is achieved with a circuit that has the features as disclosed herein, and a method that has the features as disclosed herein.

Further advantageous measures are also described herein, which can be combined with one another in order to obtain further advantages.

The object is achieved with a circuit for determining a dither amplitude that has an interface for receiving DC voltage signals and a current module for receiving the DC voltage signals and generating a direct current on the basis of the DC voltage signals and for generating a dither signal, and a dither current on the basis thereof, which is applied to the direct current in the form of a dither signal in order to obtain a drive current formed by combining the direct current with the dither current, or to modulate the direct current in the form of a directly modulated drive current until it corresponds to a direct current to which the dither current has been applied, wherein the current module contains at least one quantization threshold, and an output channel coupled to the circuit for controlling at least one load with the drive current, wherein the current module is configured to artificially modulate the amplitude of the dither signal or the directly modulated drive current with an amplitude modulation deviation on a periodic basis, wherein the amplitude modulation deviation is such that the a least one quantization threshold will be reliably exceeded, and there is a reverse current detection unit that is configured to generate numerous quantized digital values in a time period on the basis of the drive current flowing through the load, such that the dither amplitude can be determined from the numerous digital values.

It has been realized according to the present disclosure that the key value for determining the precise momentary current flowing through the load/actuator, and with which the movement of the actuator can be determined precisely, is the precise dither amplitude.

A precise determination of the dither amplitude is therefore necessary for determining the current and therefore the speed of the actuator. It has been realized according to the present disclosure that circuits are not normally able to provide a precise dither amplitude. A precise measurement may take place within the circuit, but it has also been realized that the lowest-order bits are cut off during the transmission due to the limited bit width of the output register in question. This artificially raises the quantization threshold for the circuit. The resulting resolution may be as much as ten times the required resolution, depending on the design of the circuit.

According to various embodiments of the present disclosure, the amplitude dither signal and therefore the drive current or just the drive current may be artificially modulated on a periodic basis with an amplitude modulation deviation. The modulation deviation is selected in this case such that the quantization threshold for the current module is reliably exceeded.

There is also a reverse current detection unit that can be configured as a current feedback circuit, which is configured to generate numerous quantized digital values in a time period on the basis of the drive current flowing through the load, such that the dither amplitude can be determined from the numerous digital values. This means that the measured modulated feedback drive current is calculated as a quantized digital value over a longer period of time. The resolution and the dither amplitude can be determined precisely therefrom.

The current drive current (load current) can be determined by the reverse current detection unit using a shunt resistor upstream of the load (actuator) based on the voltage drop in the shunt resistor. Other current detection technologies can also be used.

The resolution and therefore the precision of the measurement of the dither amplitude is increased with the circuit according to the present disclosure.

Despite the lower resolution of the applied dither amplitude, or the directly modulated output current, a high-resolution current signal is generated with the present disclosure.

There is a modulator (pulse-width modulator) in another embodiment, which is coupled to the current module and is configured to generate a modulated modulation output signal on the basis of the directly modulated drive current or the drive current generated with a dither signal applied thereto and a defined modulation pattern.

The drive current can be controlled using a digital current control valve, for example, that can only be in either an open or closed setting, with no intermediate settings. This can take place in the manner of pulse-width modulation, for example.

This modulation output signal can be a binary signal, for example, which has only two states (on, off). A device (magnetic anchor) for controlling the current flowing through an actuator can be controlled therewith.

In another embodiment, the reverse current detection unit can be configured to detect the directly modulated drive current or the drive current generated on the basis of the dither signal applied thereto, and detect its minimum values as quantized digital minimum values and maximum values as quantized digital maximum values. The maximum and minimum values of the drive current can then be quantized by the modulated dither signal, which contains an amplitude modulation deviation, such that the at least one quantization threshold is reliably exceeded, or by the directly modulated drive current, which contains an amplitude modulation deviation, such that the at least one quantization threshold is reliably exceeded. A mean value is then preferably determined for both the digital minimum value and digital maximum value over a predefined time period.

In another embodiment, the dither amplitude can be determined as the difference between the mean digital minimum value and mean digital maximum value over the predefined time period. This enables a precise determination of the dither amplitude. The directly modulated drive current is also directly modulated in this case with an amplitude that corresponds to the dither amplitude, such that the digital minimum value and digital maximum value can be determined over the predefined time period, with which the dither amplitude can also be calculated.

In another embodiment, the current module can comprise a current regulator and a logic circuit. The logic circuit in this case is connected to the interface. The logic circuit is configured to generate the direct current on the basis of the DC voltage signal, and to generate a dither signal and dither current on the basis thereof, and to apply these to the direct current to obtain the actual drive current.

There can also be a separate summing unit. The logic circuit can also be configured to model the direct current directly, such that it corresponds to a direct current with a dither current applied thereto. The drive current generated in this manner is sent to a current regulator that is connected to a modulator in another embodiment, for example, in which the current regulator generates a desired duty cycle for the modulator.

The logic circuit can also preferably be configured to generate a dither signal on the basis of the direct current and a dither current on the basis thereof, and to apply this to the direct current to obtain a drive current, or to artificially modulate the amplitude of the direct current with an amplitude modulation deviation on a periodic basis to obtain the directly modulated drive current.

The logic circuit in another embodiment is also configured such that the shape of the dither signal or the directly modulated drive current is either triangular or in the form of a sine wave.

In another embodiment, the reverse current detection unit is configured to determine the drive current flowing through the load on the basis of a voltage drop in a shunt resistor coupled to the load.

In another embodiment, the circuit is also configured to generate the dither signal and dither current taking the drive current flowing through the load into account, or to modulate the direct current forming the directly modulated drive current taking the drive current actually flowing through the load into account.

The circuit is configured in particular as an integrated circuit. The object is also achieved with a method for determining a dither amplitude, comprising the steps:
receiving DC voltage signals through a circuit,
generating a direct current by a current module on the basis of the DC voltage signals and a dither signal and generating a dither current, which is applied to the direct current as a dither current, to obtain a drive current formed by combining the direct current with the dither current, or modulating the direct current as a directly modulated drive current, until it corresponds to a direct current to which the dither current has been applied, wherein the current module contains at least one quantization threshold, wherein the amplitude of the dither signal or the directly modulated drive current is artificially modulated with an amplitude modulation deviation on a periodic basis, wherein the amplitude modulation deviation is such that the at least one quantization threshold is reliably exceeded, and
controlling at least one load coupled to the circuit with the drive current,
generating numerous quantized digital values in a time period on the basis of the drive current flowing through the load and determining the dither amplitude from the numerous digital values.

The advantages of the circuit according to the present disclosure can be applied to the method. In particular, the method is configured to be executed on the circuit according to the present disclosure.

In another embodiment, the minimum values of the directly modulated drive current or the drive current generated by the dither signal applied thereto can be detected as quantized digital minimum values, and the maximum values can be detected as quantized digital maximum values.

In another embodiment, a mean value can be determined for both the digital minimum value and digital maximum value over a predefined time period, wherein the dither amplitude is determined as the difference between the mean digital minimum value and the mean digital maximum value over the predefined time period.

In another embodiment, the shape of the dither signal or the directly modulated drive current is either triangular or in the form of a sine wave.

Further properties and advantages of the present disclosure can be derived from the following description in reference to the drawings.

### BRIEF DESCRIPTION OF THE DRAWINGS

FIG. 1 shows a schematic illustration of the circuit according to various embodiments;

FIG. 2 shows a schematic diagram in which a precise dither current is determined; and

FIG. 3 shows a schematic illustration of the method and the circuit.

### DETAILED DESCRIPTION

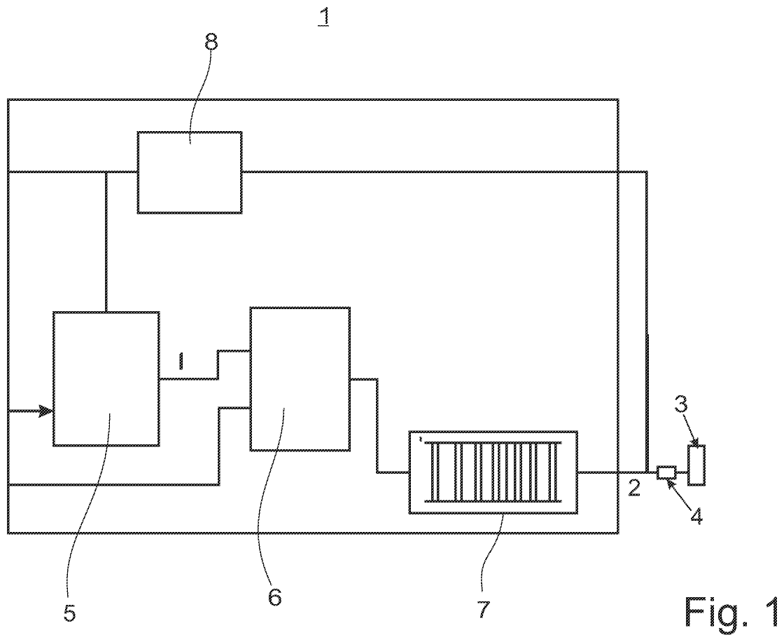

FIG. 1 shows the circuit 1 according to the present disclosure, with a quantization threshold (quantization resolution).

This circuit contains an interface (not shown), which is connected to a controller unit (not shown), by way of example. The controller unit can be connected to a supply circuit.

The circuit 1 is also connected to an output channel 2 for controlling at least one load 3, which comprises an actuator, for example. This electric actuator can comprise a coil for generating a magnetic field, for example, wherein the magnetic field acts on a magnetic anchor, the position of which is affected by a drive current flowing through the coil. The electric actuator 3 acts as an electric load in this case.

The circuit can also be used to control other actuators, etc.

The current flowing through the coil can be controlled by a current control valve (not shown) in particular, which can only be open or closed. A PWM regulator, i.e. a pulse-width modulator 7 can be used to control the current control valve, which generates a defined modulation pattern (pulse-width modulation) for a modulation output signal for the control. The pulse-width modulator 7 is integrated in the circuit 1 in this case.

A shunt resistor 4 can be placed upstream of the actuator 3 in the current path (output channel 2).

The circuit can form an integrated circuit in particular.

The circuit 1 also contains a logic circuit 5 connected to the interface. DC voltage signals are transmitted from the controller unit to the circuit 1 via the interface.

The logic circuit 5 then generates a direct current and a dither signal on the basis of the DC voltage signals. The amplitude of the dither signal is artificially modulated. The modulation deviation is selected such that the quantization threshold for the circuit 1 is reliably exceeded.

The period of the dither signal is either triangular or in the form of a sine wave.

The logic circuit 5 also generates a dither current on the basis of the dither signal. This is applied by the logic circuit 5 to the direct current such that a drive current I is generated. A summing unit can also be integrated in the logic circuit 5, or connected downstream thereof, which then combines the direct current and the dither current.

A period drive current I is obtained by the combination, which is sent to the current regulator 6. An arbitrary known control pattern can be implemented in the current regulator 6.

The current regulator 6 can be a proportional integral (PI) controller, a proportional (P) controller, or a proportional integral differential (PID) controller, or some other type of regulator, by way of example.

The current regulator 6 determines a desired duty cycle for a control circuit on the basis of the drive current I, in this case a pulse-width modulator 7, for controlling the current flowing through the actuator 3, or load.

There is also a reverse current detection unit 8 that determines the current that is actually flowing through the actuator 3, e.g. by determining the voltage drop in the shunt resistor 4. This means that the actual current flowing through the actuator is also fed back to the reverse current detection unit 8 and determined there.

The reverse current detection unit 8 can contain an analog-digital converter with the quantization threshold.

The reverse current detection unit 8 can detect the minimum value of the drive current I as a quantized digital minimum value and the maximum value of the drive current I as a quantized digital maximum value.

The reverse current detection unit 8 detects the quantized digital minimum value and the quantized digital maximum value over a predefined time period. The reverse current detection unit 8 also detects the quantized digital minimum value and the quantized digital maximum value continuously.

Consequently, a mean value can be determined for the digital minimal values and digital maximum values over the predefined time period, and the dither amplitude can be determined as the difference between the mean digital minimum value and the mean digital maximum value over the predefined time period.

The resolution and therefore the precision of the measurement of the dither amplitude is increased in this manner.

By precisely determining the dither amplitude, the speed of the actuator 3 can then be derived through a corresponding computation.

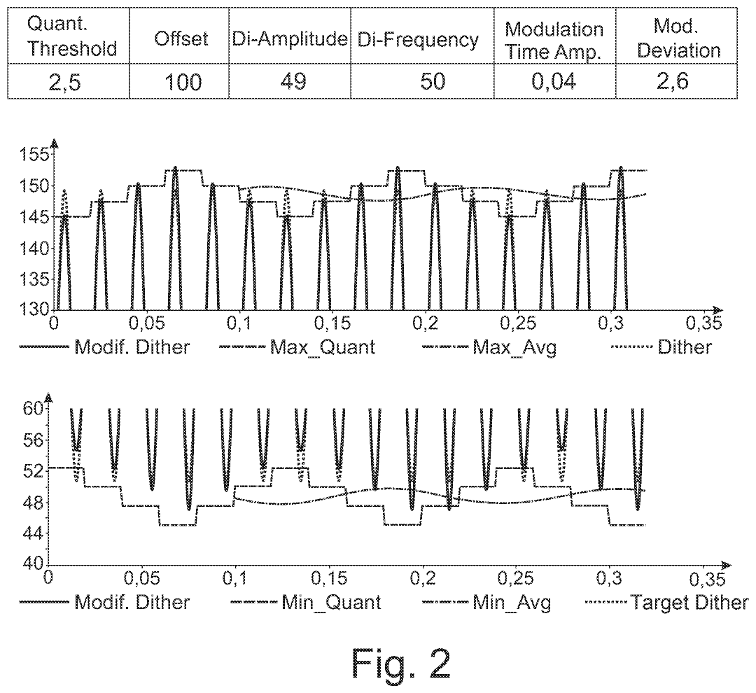

FIG. 2 shows how a precise dither current is determined in the form of a graph.

This represents a key value for determining actuator speeds.

A precise determination of the dither amplitude is necessary for determining the speed of the actuator 3. Because circuits 1, e.g. integrated circuits, usually only make imprecise dither amplitudes available, it is not possible to precisely determine actuator speeds therewith. Although a measurement takes place within the circuit, the lowest value bits are cut off during the transmission due to the low bit width in the output register. This results in an artificial raising of the quantization threshold for the circuit, such that the dither amplitude can only be imprecisely determined/indicated.

In this example, the offset for the direct current is 100. The quantization threshold has a value of 2.5.

The dither current (dither) generated by the logic circuit 5 is applied to the direct current in obtain the drive current I. The amplitude of the dither signal is artificially modulated by the logic circuit 5 for this. The modulation deviation (amplitude deviation) is selected such that the quantization threshold for the circuit 1 is reliably exceeded. The modulation deviation in this example is 2.6.

A modified dither (drive current) is therefore obtained by applying the periodic dither current.

Quantized digital maximum values (Max-Quant) and quantized digital minimum values (Min-Quant) can then be generated by the reverse current detection unit 8 and the artificial amplitude modulation of the drive current I. Furthermore, the reverse current detection unit 8 can also contain a computing unit for obtaining mean values for the quantized digital maximum values (Max-Quant) labeled Max_Avg.

Max_Avg is therefore the mean digital maximum value obtained by applying the periodic dither current.

Furthermore, the computing unit can determine a mean value for the quantized digital minimum values (Min-Quant).

Min_Avg is therefore the mean digital minimum value obtained by applying the periodic dither current.

The difference between the mean digital minimum value (Min-Quant) and the mean digital maximum value (Max-Quant) corresponds to the amplitude of the dither current that is applied.

The dither amplitude, and thus the current flowing through the actuator 3, can therefore be determined precisely in this manner. The actuator speed can be determined from this.

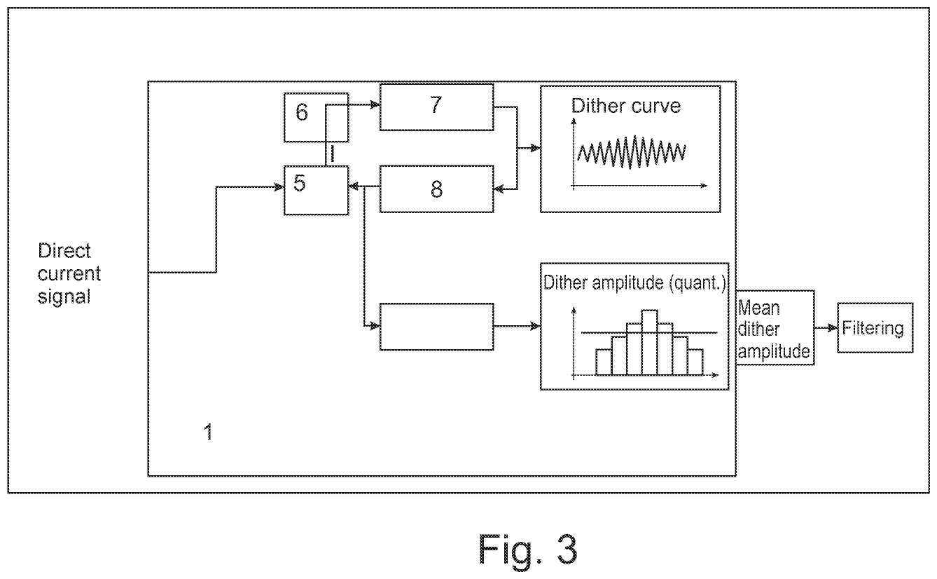

FIG. 3 shows a schematic illustration of the method and the circuit 1.

Therein, the DC voltage signal is first sent to a logic circuit 5.

This generates the direct current on the basis of the DC voltage signal. A dither signal and dither current are also generated on the basis of the direct current, which are then applied to the direct current to obtain the drive current I in which the amplitude is artificially modulated. The modulation deviation for this is selected such that the quantization threshold for the circuit 1 is reliably exceeded.

Alternatively, the logic circuit 5 can also vary the direct current in order to obtain the drive current I, such that it corresponds to if a dither signal were applied thereto.

The drive current I is subsequently sent to the current regulator 6, which sends a desired duty cycle to a control circuit for a downstream pulse-width modulator 7.

The drive current I is processed in the pulse-width modulator 7 such that the actuator 3 can be controlled by a magnetic anchor, for example. The pulse-width modulator 7 generates the desired duty cycle in a control circuit for the actuator 3.

The drive current I flowing through the actuator 3 is subsequently detected on the basis of the voltage drop in the shunt resistor 4 by the reverse current detection unit 8.

This information is sent to the logic circuit 5, which generates the dither signal and the dither current, or the modulation of the direct current, on the basis thereof.

Furthermore, the drive current I is then quantized into the digital maximum value Max_Quant and the digital minimum value Min_Quant, this being carried out continuously over a longer period of time.

The mean maximum value Max_Avg and mean minimum value Min_Avg are then determined by averaging the digital minimal values Min_Quant and digital maximum values Max_Quant.

The difference between the mean maximum value Max_Avg and mean minimum value Min_Avg therefore represents the dither amplitude with sufficient precision (filtering).

Despite a low resolution of the dither amplitude in the circuit, a high-resolution current signal for the drive current is generated with the method according to the present disclosure and the circuit 1 according to the present disclosure.

At the receiver, an averaging of the dither amplitudes that are detected over a predefined time period therefore takes place according to the present disclosure. Consequently, the resolution, and therefore the precision of the dither amplitude measurement, are increased.

### REFERENCE SYMBOLS

1 circuit

2 output signal

3 actuator

4 shunt

5 logic circuit

6 current regulator

7 pulse-width modulator

8 reverse current detection unit

I drive current

1. A dither amplitude circuit for determining a dither amplitude, comprising:
an interface configured to receive DC voltage signals;
a return current detection circuit;
an output channel; and
a current circuit configured to:
receive the DC voltage signals;
generate a direct current on a basis of the DC voltage signals;
generate a dither signal;
generate a dither current on a basis of the dither signal;
apply the dither current to the direct current in order to obtain a drive current by at least one of combining the direct current and the dither current, or modulating the direct current to obtain a directly modulated drive current, until the directly modulated drive current corresponds to the direct current to which the dither current has been applied,
wherein the current circuit comprises at least one quantization threshold,
wherein the output channel is configured to control at least one load with the drive current,
wherein the current circuit is further configured to artificially modulate an amplitude of at least one of the dither signal or the directly modulated drive current with an amplitude modulation deviation on a periodic basis,
wherein the amplitude modulation deviation is such that the at least one quantization threshold is reliably exceeded,
wherein the return current detection circuit configured to:
generate numerous quantized digital values in a time period on a basis of the drive current flowing through the load; and
determine the dither amplitude from the numerous digital values.

2. The dither amplitude circuit according to claim 1, further comprising:
a modulator circuit coupled to the current circuit, which is configured to generate a modulated modulation output signal on a basis of:
the directly modulated drive current, or
the drive current generated by applying the dither signal and a defined pulse-width modulation pattern.

3. The dither amplitude circuit according to claim 1, wherein the return current detection circuit is configured to:
detect the directly modulated drive current or the drive current generated on the basis of the applied dither signal; and
detect a minimum value as a quantized digital minimum value and a maximum value as a quantized digital maximum value.

4. The dither amplitude circuit according to claim 3, wherein the return current detection circuit is configured to:
determine a plurality of digital minimum values and a plurality of digital maximum values over the time period.

5. The dither amplitude circuit according to claim 4, wherein the return current detection circuit is configured to:
determine the dither amplitude as a difference between a mean digital minimum value of the plurality of digital minimum values and a mean digital maximum value of the plurality of digital maximum values over the time period.

6. The dither amplitude circuit according to claim 1, wherein the current circuit comprises:
a current regulator; and
a logic circuit.

7. The dither amplitude circuit according to claim 6, wherein the logic circuit is configured to:
generate the dither signal on a basis of the direct current;
generate the dither current on the basis of the dither signal; and
apply the dither current to the direct current to obtain the drive current, or to artificially modulate the amplitude of the direct current with the amplitude modulation deviation on the periodic basis to obtain the directly modulated drive current.

8. The dither amplitude circuit according to claim 6, wherein the logic circuit is configured to:
form the dither signal or the directly modulated drive current such that a shape thereof is either triangular or in the form of a sine wave.

9. The dither amplitude circuit according to claim 1, wherein the return current detection circuit is configured to:
determine the drive current flowing through the load on a basis of a voltage drop in a shunt resistor coupled to the load.

10. The dither amplitude circuit according to claim 1, wherein the dither amplitude circuit is configured to:
generate the dither signal and the dither current taking the drive current flowing through the load into account, or
to modulate the direct current in the form of the directly modulated drive current taking the drive current actually flowing through the load into account.

11. A method for determining a dither amplitude, comprising:
receiving, by a current circuit, DC voltage signals;
generating, by the current circuit, a direct current on a basis of the DC voltage signals;
generating, by the current circuit, a dither signal;
generating, by the current circuit, a dither current that is applied to the direct current to obtain a drive current formed by:
combining the direct current with the dither current, or
modulating the direct current as a directly modulated drive current, until it corresponds to a direct current to which the dither current has been applied,
artificially modulating the amplitude of the dither signal or the directly modulated drive current with an amplitude modulation deviation on a periodic basis such that at least one quantization threshold of the current circuit is reliably exceeded;
controlling at least one load with the drive current;
generating numerous quantized digital values in a time period on a basis of the drive current flowing through the load; and
determining a dither amplitude from the numerous digital values.

12. The method according to claim 11, further comprising:
detecting minimum values and maximum of the directly modulated drive current or the drive current generated on the basis of the dither signal applied thereto, as quantized digital minimal values and quantized digital maximum values, respectively.

13. The method according to claim 12, further comprising determining mean values for both the digital minimum values and digital maximum values over the time period.

14. The method according to claim 13, further comprising determining the dither amplitude as a difference between the mean digital minimum value and the mean digital maximum value over the time period.

15. The method according to claim 11, wherein the dither signal or the directly modulated drive current is triangular or in the form of a sine wave.
